(19) United States
(12) Patent Application Publication
(10) Pub. No.: US 2021/0399397 A1
(43) Pub. Date: Dec. 23, 2021

(54) HIGH-FREQUENCY SIGNAL TRANSMISSION STRUCTUREAND METHOD FOR MANUFACTURING THE SAME

(71) Applicants: QING DING PRECISION ELECTRONICS (HUAIAN) CO.,LTD, Huai an (CN); Avary Holding (Shenzhen) Co., Limited., Shenzhen (CN)

(72) Inventors: HSIAO-TING HSU, New Taipei (TW); MING-JAAN HO, New Taipei (TW); XIAN-QIN HU, Shenzhen (CN); FU-YUN SHEN, Shenzhen (CN)

(21) Appl. No.: 16/916,296

(22) Filed: Jun. 30, 2020

(30) Foreign Application Priority Data
Jun. 19, 2020 (CN) 202010567081.9

(51) Int. Cl. H01P 3/08; H01P 11/00; H05K 1/02; H05K 1/11; H05K 3/36; H05K 1/14

(52) U.S. Cl. CPC H01P 3/08; H01P 11/003; H05K 1/144; H05K 1/115; H05K 3/36; H05K 1/0237

(57) ABSTRACT

A high-frequency signal transmission structure capable of transmitting high frequency signals with reduced attenuation includes a first wiring board and a second wiring board. The first wiring board includes a first conductor layer, a second conductor layer, and a first base film layer sandwiched between the first conductor layer and the second conductor layer. The second wiring board includes a second base film layer and a third conductor layer. the second base film layer covers the surface of the first conductor layer facing away from the first base film layer. The first base film layer and the second base film layer surround the first conductor layer and both include an aerogel film layer having an air to gel ratio by volume of 80-99%. A method for manufacturing the high-frequency signal transmission structure is also disclosed.

### FIELD

The subject matter herein generally relates to radio transmission, in particular to a high-frequency signal transmission structure and a method for manufacturing the same.

### BACKGROUND

In high-frequency electronic signal transmissions, attenuation of the transmission signal is mainly a result of dielectric loss. Dielectric loss is positively correlated with dielectric loss factor and dielectric constant. In order to reduce the transmission loss, a liquid crystal polymer with a low dielectric constant can be used as the base film layer covering the transmission line. However, such material still has a relatively high dielectric loss.

### BRIEF DESCRIPTION OF THE DRAWINGS

Implementations of the present technology will now be described, by way of embodiment, with reference to the attached figures.

FIG. 1 is a cross-sectional view of an embodiment of a high-frequency signal transmission structure.

FIG. 2 is a cross-sectional view of an embodiment of a first wiring board.

FIG. 3 is a cross-sectional view of an embodiment of a second wiring board.

FIG. 4 is a cross-sectional view showing the second wiring board of FIG. 3 pressed onto the first wiring board of FIG. 2.

FIG. 5 is a cross-sectional view of second blind vias and first blind vias in the structure shown in FIG. 4.

### DETAILED DESCRIPTION

Implementations of the disclosure will now be described, by way of embodiments only, with reference to the drawings. The disclosure is illustrative only, and changes may be made in the detail within the principles of the present disclosure. It will, therefore, be appreciated that the embodiments may be modified within the scope of the claims.

Unless otherwise defined, all technical terms used herein have the same meaning as commonly understood by one of ordinary skill in the art. The technical terms used herein are to provide a thorough understanding of the embodiments described herein, but are not to be considered as limiting the scope of the embodiments.

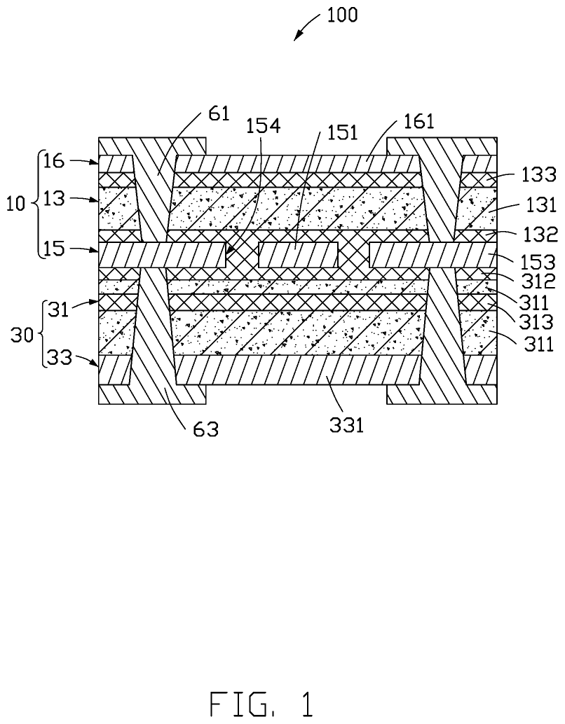

FIG. 1 illustrates a high-frequency signal transmission structure 100 according to one embodiment. The high-frequency signal transmission structure 100 is applied to a circuit board and includes a first wiring board 10 and a second wiring board 30 covering a surface of the first wiring board 10.

The first wiring board 10 is a double-sided wiring substrate, and includes a first base film layer 13, a first conductor layer 15, and a second conductor layer 16. The first base film layer 13 is sandwiched between the first conductor layer 15 and the second conductor layer 16.

The first conductor layer 15 is made of metal, such as copper. The first conductor layer 15 includes a transmission line 152 and two ground lines 153. The two ground lines 153 are arranged at intervals on both sides of the transmission line 151. There is a gap 154 formed between the transmission line 151 and each of the two ground lines 153.

The second conductor layer 16 is made of metal, such as copper. The second conductor layer 16 includes a circuit pattern layer (not shown) and a first ground layer 161 spaced from the circuit pattern layer. The first ground layer 161 is arranged to correspond to the transmission line 151. In the embodiment, the first ground layer 161 is a copper plated layer or a copper foil.

The first base film layer 13 includes an aerogel film layer 131, a first waterproof layer 132, and a second waterproof layer 133. The aerogel film layer 131 is sandwiched between the first waterproof layer 132 and the second waterproof layer 133. The aerogel film layer 131 includes a polymer having a low dielectric constant, such as polyimide (PI), polyethylene terephthalate (PET), liquid crystal polymer (LCP), ethylene naphthalate (PEN), or polytetrafluoroethylene. A proportion of air in the aerogel film layer 131 is about 80-99% such that the aerogel film layer 131 has a low dielectric constant.

In an alternative embodiment, the aerogel film layer 131 has a glass transition temperature (Tg) of more than 340□. In the embodiment, the aerogel film layer 131 includes polyimide, polyacrylic acid, and silicon dioxide. In an alternative embodiment, the aerogel film layer 131 may include other polymers and silicon dioxide. In an alternative embodiment, the aerogel film layer 131 may be formed of polyimide and a polymer with a low glass transition temperature after removing the polymer with a low glass transition temperature by thermal cracking.

In the embodiment, the aerogel film layer 131 has a thickness of about 25˜150 μm, so that the first base film layer 13 has good resistance to pressure and will not collapse during a lamination process.

The first waterproof layer 132 and the second waterproof layer 133 are used to prevent external moisture from entering the aerogel film layer 131. In the embodiment, the first waterproof layer 132 covers the surface of the first conductor layer 15 facing the first base film layer 13, and the second waterproof layer 133 covers the surface of the second conductor layer 16 facing the first base film layer 13. Each of the first waterproof layer 132 and the second waterproof layer 133 has a thickness of about 2˜20 μm.

Each of the first waterproof layer 132 and the second waterproof layer 133 may include a hydrophobic material, such as hydrocarbon or a fluorocarbon material such as polytetrafluoroethylene or perfluoroalkoxy alkane. The first waterproof layer 132 and the second waterproof layer 133 may be made of the same or different materials. Each of the first waterproof layer 132 and the second waterproof layer 133 has a dielectric constant of about 2.0˜2.4.

The second wiring board 30 is a single-sided circuit substrate, and includes a second base film layer 31 and a third conductor layer 33 covering a surface of the second base film layer 31. The second base film layer 31 covers the side of the first conductor layer 15 facing away from the first base film layer 13, and the third conductor layer 33 covers the side of the second wiring board 30 facing away from the first conductor layer 15.

The third conductor layer 33 is made of metal such as copper. The third conductor layer 33 includes a circuit pattern layer (not shown) and a second ground layer 331 spaced from the circuit pattern layer. The second ground layer 331 is arranged to correspond to the transmission line 151. In the embodiment, the second ground layer 331 is a copper plated layer or a copper foil.

The second base film layer 31 includes two aerogel film layers 311, a first waterproof layer 312, and a second waterproof layer 313. The first waterproof layer 312 covers the surface of the first conductor layer 15 facing away from the first base film layer 13. One of the two aerogel film layers 311 is sandwiched between the first waterproof layer 312 and the second waterproof layer 313, and the other one of the two aerogel film layers 311 is sandwiched between the second waterproof layer 313 and the third conductor layer 33. In an alternative embodiment, the second base film layer 31 may include only one aerogel film layer 311.

In the embodiment, the first waterproof layer 132 of the first base film layer 13 and the first waterproof layer 312 of the second base film layer 31 further infill the gaps 154 to completely cover the transmission line 151, thus protecting the single line 151 from oxidation.

Each of the two aerogel film layers 311 includes a polymer having a low dielectric constant, such as polyimide (PI), polyethylene terephthalate (PET), liquid crystal polymer (LCP), ethylene naphthalate (PEN), or polytetrafluoroethylene. The proportion of air in each aerogel film layer 311 is about 80-99% such that the aerogel film layer 311 has a low dielectric constant. In the embodiment, the second base film layer 31 has a dielectric constant of about 1.14 to 2.4.

In an alternative embodiment, each aerogel film layer 311 has a glass transition temperature (Tg) of more than 340□. In the embodiment, each aerogel film layer 311 includes polyimide, polyacrylic acid, and silicon dioxide. In an alternative embodiment, each aerogel film layer 311 may include other polymers and silicon dioxide. In an alternative embodiment, each aerogel film layer 311 may be formed of polyimide and a polymer with a low glass transition temperature after removing the polymer with a low glass transition temperature by thermal cracking.

In the embodiment, each aerogel film layer 311 has a thickness of about 25˜150 μm, so that the second base film layer 31 has a good pressure resistance and does not collapse during a lamination process.

It is to be understood, the numbers of first and second wiring boards 10 and 30 may be set according to needs, so as to obtain a high-frequency signal transmission structure 100 having more conductor layers.

The high-frequency signal transmission structure 100 further includes two groups of conductive holes located on both sides of the transmission line 151. The two groups of conductive holes are respectively electrically connected to the two ground lines 153. Each of the two groups includes a first conductive hole 61 and a second conductive hole 63 on two surfaces of one ground line 153. The first conductive hole 61 electrically connects the one ground line 153 and the first ground layer 161. The second conductive hole 63 electrically connects the one ground line 153 and the second ground layer 331. The two groups of conductive holes, the two ground lines 153, the first ground layer 161, and the second ground layer 331 surround the transmission line 151 and together act as a shield to keep external electromagnetic interference out of the transmission line 151.

In the high-frequency signal transmission structure 100, the transmission line 151 is surrounded by base film layers including aerogel film layers which have a very low dielectric constant, and attenuation of the transmission line 151 during transmission is thereby reduced. The transmission line 151 is coated with waterproof layers to protect against oxidation of the transmission line 151.

One embodiment of a method for manufacturing a high-frequency signal transmission structure includes the steps of:

S1, providing a first wiring board including a first conductor layer, a second conductor layer, and a first base film layer sandwiched between the first conductor layer and the second conductor layer;

S2, providing a second wiring board including a second base film layer and a third conductor layer on a surface of the second base film layer;

S3, pressing the second wiring board onto the first wiring board, the second base film layer covering the surface of the first conductor layer facing away from the first base film layer.

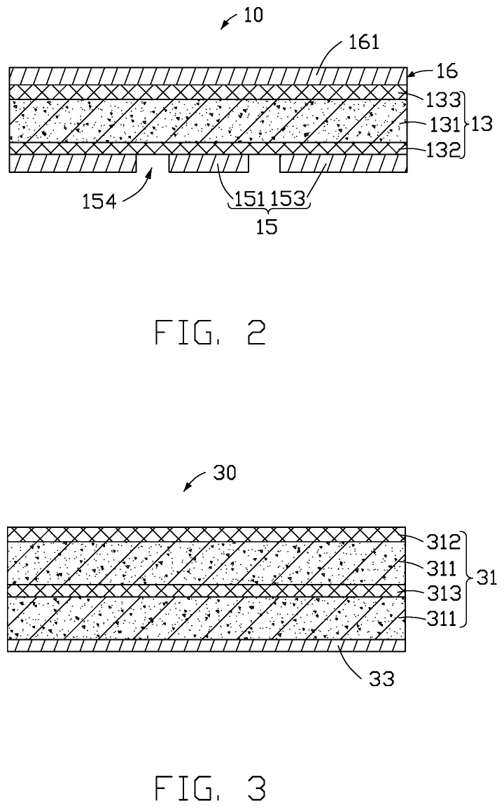

Referring to FIG. 2, in step S1, a first wiring board 10 is provided, the wiring board 10 including a first conductor layer 15, a second conductor layer 16, and a first base film layer 13 sandwiched between the first conductor layer 15 and the second conductor layer 16.

The first conductor layer 15 is made of metal, such as copper. The first conductor layer 15 includes a transmission line 152 and two ground lines 153. The two ground lines 153 are arranged at intervals on both sides of the transmission line 151. There is a gap 154 formed between the transmission line 151 and each of the two ground lines 153.

The second conductor layer 16 is made of metal, such as copper. The second conductor layer 16 includes a circuit pattern layer (not shown) and a first ground layer 161 spaced from the circuit pattern layer. The first ground layer 161 is arranged to correspond to the transmission line 151. In the embodiment, the first ground layer 161 is a copper plated layer or a copper foil. Each of the first conductor layer 15 and the second conductor layer 16 may be formed on a copper layer by using a photo-lithography method.

The first base film layer 13 includes an aerogel film layer 131, a first waterproof layer 132, and a second waterproof layer 133. The aerogel film layer 131 is sandwiched between the first waterproof layer 132 and the second waterproof layer 133. The aerogel film layer 131 may be formed by coating a hydrogel layer on a support element such as the first waterproof layer 132 or the second waterproof layer 133 and baking the hydrogel layer in place.

The aerogel film layer 131 includes a polymer having a low dielectric constant, such as polyimide (PI), polyethylene terephthalate (PET), liquid crystal polymer (LCP), ethylene naphthalate (PEN), or polytetrafluoroethylene. The proportion of air in the aerogel film layer 131 is about 80-99% such that the aerogel film layer 131 has a low dielectric constant. In the embodiment, the first base film layer 13 has a dielectric constant of about 1.14 to 2.4.

In an alternative embodiment, the aerogel film layer 131 has a glass transition temperature (Tg) of more than 340□. In the embodiment, the aerogel film layer 131 includes polyimide, polyacrylic acid, and silicon dioxide. In an alternative embodiment, the aerogel film layer 131 may include other polymers and silicon dioxide. In an alternative embodiment, the aerogel film layer 131 may be formed of polyimide and a polymer with a low glass transition temperature, after removing the polymer with a low glass transition temperature by thermal cracking.

In the embodiment, the aerogel film layer 131 has a thickness of about 25˜150 μm, so that the first base film layer 13 has a good pressure resistance and does not collapse during a lamination process.

The first waterproof layer 132 and the second waterproof layer 133 prevent external moisture from entering the aerogel film layer 131. In the embodiment, the first waterproof layer 132 covers the surface of the first conductor layer 15 facing the first base film layer 13, and the second waterproof layer 133 covers the surface of the second conductor layer 16 facing the first base film layer 13. Each of the first waterproof layer 132 and the second waterproof layer 133 has a thickness of about 2˜20 μm.

Each of the first waterproof layer 132 and the second waterproof layer 133 may include a hydrophobic material, such as hydrocarbon or a fluorocarbon material such as polytetrafluoroethylene or perfluoroalkoxy alkane. The first waterproof layer 132 and the second waterproof layer 133 may be made of the same or different materials. Each of the first waterproof layer 132 and the second waterproof layer 133 has a dielectric constant of about 2.0˜2.4.

Referring to FIG. 3, in step S2, a second wiring board 30 is provided, the second wiring board 30 including a second base film layer 31 and a third conductor layer 33 disposed on a surface of the second base film layer 31.

The third conductor layer 33 is made of metal such as copper. The third conductor layer 33 includes a circuit pattern layer (not shown) and a second ground layer 331 spaced from the circuit pattern layer. The second ground layer 331 is arranged to correspond to the transmission line 151. In the embodiment, the second ground layer 331 is a copper plated layer or a copper foil.

The second base film layer 31 includes two aerogel film layers 311, a first waterproof layer 312, and a second waterproof layer 313. The first waterproof layer 312 covers the surface of the first conductor layer 15 facing away from the first base film layer 13. One of the two aerogel film layers 311 is sandwiched between the first waterproof layer 312 and the second waterproof layer 313, and the other one of the two aerogel film layers 311 is sandwiched between the second waterproof layer 313 and the third conductor layer 33. In an alternative embodiment, the second base film layer 31 may include only one aerogel film layer 311.

Each of the two aerogel film layers 311 includes polymer having a low dielectric constant, such as polyimide (PI), polyethylene terephthalate (PET), liquid crystal polymer (LCP), ethylene naphthalate (PEN), or polytetrafluoroethylene. The proportion of air in each aerogel film layer 311 is about 80-99% such that the aerogel film layer 311 has a low dielectric constant. In the embodiment, the second base film layer 31 has a dielectric constant of about 1.14 to 2.4.

In an alternative embodiment, each aerogel film layer 311 has a glass transition temperature (Tg) of more than 340□. In the embodiment, each aerogel film layer 311 includes polyimide, polyacrylic acid, and silicon dioxide. In an alternative embodiment, each aerogel film layer 311 may include other polymers and silicon dioxide. In an alternative embodiment, each aerogel film layer 311 may be formed of polyimide and a polymer with a low glass transition temperature after removing the polymer with a low glass transition temperature by thermal cracking.

In the embodiment, each aerogel film layer 311 has a thickness of about 25˜150 μm, that the second base film layer 31 has a good pressure resistance and does not collapse during a lamination process.

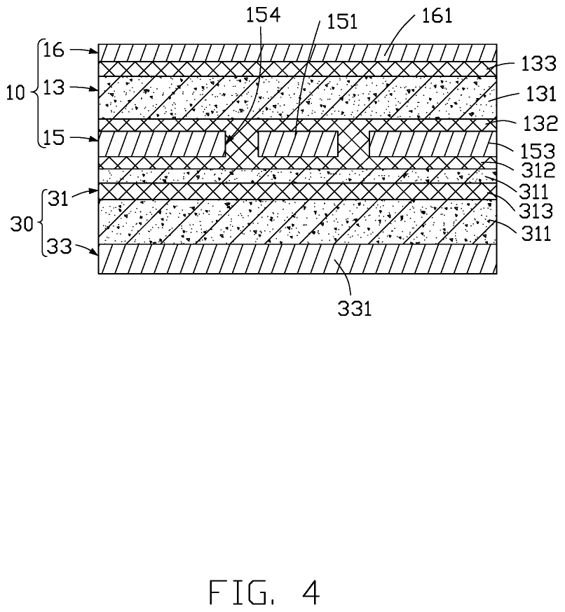

Referring to FIG. 4, in step S3, the second wiring board 30 is pressed onto the first wiring board 10, the second base film layer 31 covering the side of the first conductor layer 15 facing away from the first base film layer 13.

During pressing, the first waterproof layer 132 of the first base film layer 13 and the first waterproof layer 312 of the second base film layer 31 further infill the gaps 154 to completely cover the transmission line 151, thus preventing oxidation.

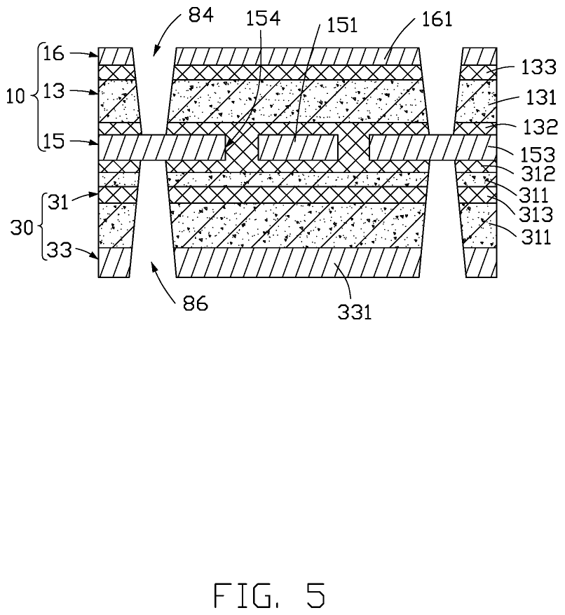

Referring to FIGS. 1 and 5, it is to be understood, after step S3, the method further includes a step of forming two groups of conductive holes on both sides of the transmission line 151. One of the two groups electrically connects one of the two ground lines 153, the first ground layer 161, and the second ground layer 331, the other one of the two groups electrically connects to the other one of the two ground lines 153, the first ground layer 161, and the second ground layer 331.

Each of the two groups includes a first conductive hole 61 and a second conductive hole 63 on two surfaces of one ground line 153. The first conductive hole 61 electrically connects the one ground line 153 and the first ground layer 161. The second conductive hole 63 electrically connects the one ground line 153 and the second ground layer 331. The two groups of conductive holes, the two ground lines 153, the first ground layer 161, and the second ground layer 331 surround the transmission line 151 and together act as a shield preventing external electromagnetic interference in the transmission line 151. The first conductive hole 61 may be formed by forming a first blind via 84 exposing one ground line 153 on the first wiring board 10 and infilling or electroplating the first blind via 84 with a conductive material. The second conductive hole 63 may be formed by forming a second blind via 86 exposing one ground line 153 on the second wiring board 30 and infilling or electroplating the second blind via 86 with a conductive material.

During manufacturing, when the second wiring board 30 is pressed onto the first wiring board 10, the base film layer does not collapse because of good pressure resistance of the aerogel film layer.

While the present disclosure has been described with reference to particular embodiments, the description is illustrative of the disclosure and is not to be construed as limiting the disclosure. Therefore, those of ordinary skill in the art can make various modifications to the embodiments without departing from the scope of the disclosure as defined by the appended claims.

What is claimed is:

1. A high-frequency signal transmission structure comprising:
a first wiring board comprising a first conductor layer, a second conductor layer, and a first base film layer sandwiched between the first conductor layer and the second conductor layer; and
a second wiring board comprising a second base film layer and a third conductor layer, the second base film layer covering the side of the first conductor layer facing away from the first base film layer, the third conductor layer disposed on the side of the second base film layer facing away from the first conductor layer;
wherein each of the first base film layer and the second base film layer includes an aerogel film layer, a proportion of air in the aerogel film layer is 80-99%.

2. The high-frequency signal transmission structure of claim 1, wherein the first conductor layer comprises a transmission line and two ground lines arranged at intervals on both sides of the transmission line, a gap is defined between the transmission line and each of the two ground lines, each of the first base film layer and the second base film layer further comprises a first waterproof layer disposed on a surface of the aerogel film layer, the first waterproof layer covers a side of the first conductor layer and infills the gap.

3. The high-frequency signal transmission structure of claim 2, wherein the first base film layer further comprises a second waterproof layer sandwiched between the second conductor layer and the aerogel film layer of the first base film layer.

4. The high-frequency signal transmission structure of claim 2, wherein the second base film layer comprises two of the aerogel film layer, one of the first waterproof layer, and a second waterproof layer; one of the two aerogel film layers is sandwiched between the first waterproof layer of the second base film layer and the second waterproof layer;
another one of the two aerogel film layers is sandwiched between the second waterproof layer and the third conductor layer.

5. The high-frequency signal transmission structure of claim 2, further comprising two groups of conductive holes electrically connected to the two ground lines respectively, wherein the second conductor layer comprises a first ground layer, the third conductor layer comprises a second ground layer, each of the two groups of conductive holes electrically connects one of the two ground lines, the first ground layer, and the second ground layer.

6. The high-frequency signal transmission structure of claim 5, wherein each of the two groups of conductive holes comprises a first conductive hole and a second conductive hole, the first conductive hole electrically connects one of the two ground lines and the first ground layer, the second conductive hole electrically connects the one of the two ground lines and the second ground layer.

7. The high-frequency signal transmission structure of claim 1, wherein the aerogel film layer comprises polyimide, polyacrylic acid, and silicon dioxide.

8. A method for manufacturing a high-frequency signal transmission structure comprising:
providing a first wiring board comprising a first conductor layer, a second conductor layer, and a first base film layer sandwiched between the first conductor layer and the second conductor layer;
providing a second wiring board comprising a second base film layer and a third conductor layer on a surface of the second base film layer;
pressing the second wiring board onto the first wiring board, the second base film layer covering the side of the first conductor layer facing away from the first base film layer, the third conductor layer disposed on the side of the second base film layer facing away from the first conductor layer, wherein each of the first base film layer and the second base film layer includes an aerogel film layer, a proportion of air in the aerogel film layer is 80-99%.

9. The method of claim 8, wherein the first conductor layer comprises a transmission line and two ground lines arranged at intervals on both sides of the transmission line, a gap is defined between the transmission line and each of the two ground lines, each of the first base film layer and the second base film layer further comprises a first waterproof layer disposed on a surface of the aerogel film layer, the first waterproof layer covers a side of the first conductor layer and infills the gap.

10. The method of claim 9, wherein the first base film layer further comprises a second waterproof layer sandwiched between the second conductor layer and the aerogel film layer of the first base film layer.

11. The method of claim 9, wherein the second base film layer comprises two of the aerogel film layer, one of the first waterproof layer, and a second waterproof layer; one of the two aerogel film layers is sandwiched between the first waterproof layer of the second base film layer and the second waterproof layer; another one of the two aerogel film layers is sandwiched between the second waterproof layer and the third conductor layer.

12. The method of claim 9, further comprising: forming two groups of conductive holes on both sides of the transmission line, wherein the second conductor layer comprises a first ground layer, the third conductor layer comprises a second ground layer, each of the two groups of conductive holes electrically connects one of the two ground lines, the first ground layer, and the second ground layer.

13. The method of claim 12, wherein each of the two groups of conductive holes comprises a first conductive hole and a second conductive hole, the first conductive hole electrically connects one of the two ground lines and the first ground layer, the second conductive hole electrically connects the one of the two ground lines and the second ground layer.

14. The method of claim 8, wherein the aerogel film layer comprises polyimide, polyacrylic acid, and silicon dioxide.
